(19) United States
(12) Patent Application Publication
(10) Pub. No.: US 2023/0051865 A1
(43) Pub. Date: Feb. 16, 2023

(54) PVD APPARATUS

(71) Applicant: Tokyo Electron Limited, Tokyo (JP)

(72) Inventors: Takuya SEINO, Tokyo (JP); Yasushi KODASHIMA, Yamanashi (JP); Naoki WATANABE, Yamanashi (JP); Hiroyuki TOSHIMA, Yamanashi (JP); Masato SHINADA, Tokyo (JP); Tetsuya MIYASHITA, Yamanashi (JP)

(73) Assignee: Tokyo Electron Limited, Tokyo (JP)

(21) Appl. No.: 17/975,619

(22) Filed: Oct. 28, 2022

Related U.S. Application Data
(63) Continuation-in-part of application No. PCT/JP2021/015661, filed on Apr. 16, 2021.
(60) Provisional application No. 63/017,787, filed on Apr. 30, 2020.
(60) Provisional application No. 63/024,153, filed on May 13, 2020.

(51) Int. Cl. C23C 14/56; C23C 14/50

(52) U.S. Cl. CPC C23C 14/568; C23C 14/50

(57) ABSTRACT

The PVD apparatus includes a chamber, a plurality of stages, a first target holder, a power supply mechanism, and a shield. The plurality of stages are provided inside the chamber, and each of the plurality of stages is configured to place at least one substrate on an upper surface thereof. The first target holder is configured to hold at least one target provided for one stage, the target being exposed to a space inside the chamber. The power supply mechanism supplies power to the target via the first target holder. The shield is provided inside the chamber and a part of the shield is disposed between a first stage and a second stage in the plurality of stages, and between a first processing space on the first stage and a second processing space on the second stage.

### CROSS-REFERENCE TO RELATED APPLICATIONS

This application is a bypass continuation-in-part application of international application No. PCT/JP2021/015661 having an international filing date of Apr. 16, 2021 and designating the United States, the international application being based upon and claiming the benefit of priorities from U.S. provisional applications No. 63/017,787, filed on Apr. 30, 2020 and No. 63/024,153, filed on May 13, 2020, the entire contents of which are incorporated herein by reference.

### TECHNICAL FIELD

Various aspects and embodiments of the present disclosure relate to a PVD apparatus.

### BACKGROUND

Patent Document 1 discloses a PVD apparatus in which a constituent substance of a target material is stacked on a substrate by physical vapor deposition (PVD).

### PATENT DOCUMENT OF THE RELATED ART

Patent Document 1: Japanese Patent Application Publication No. 2018-537849

### SUMMARY

### Technical Problem

The present disclosure provides a PVD apparatus capable of improving a throughput of layer formation processing on a plurality of substrates.

An aspect of the present disclosure is a PVD apparatus, which includes a chamber, a plurality of stages, a first target holder, a power supply mechanism, and a shield. The plurality of stages are provided inside the chamber, and each of the plurality of stages is configured to place at least one substrate on an upper surface thereof. The first target holder is configured to hold at least one target provided to face one stage, the target being exposed to a space inside the chamber. The power supply mechanism supplies power to the target via the target holder. The shield is provided inside the chamber and a part of the shield is disposed between a first stage and a second stage in the plurality of stages, and between a first processing space on the first stage and a second processing space on the second stage.

According to various aspects and embodiments of the present disclosure, it is possible to improve a throughput of layer formation processing performed on a plurality of substrates.

### BRIEF DESCRIPTION OF THE DRAWINGS

FIG. 1 is a flowchart illustrating an example of a semiconductor device manufacturing method according to an embodiment of the present disclosure.

FIG. 2 is a schematic view illustrating an example of a processing process of a substrate.

FIG. 3 is a schematic view illustrating an example of the processing process of the substrate.

FIG. 4 is a schematic view illustrating an example of the processing process of the substrate.

FIG. 5 is a schematic view illustrating an example of the processing process of the substrate.

FIG. 6 is a schematic view illustrating an example of the processing process of the substrate.

FIG. 7 is a system configuration view illustrating an example of a PVD system according to an embodiment of the present disclosure.

FIG. 8 is a schematic plan view illustrating an example of a PVD apparatus according to an embodiment of the present disclosure.

FIG. 9 is a schematic sectional view illustrating an example of a cross-section taken along line A-A of the PVD apparatus illustrated in FIG. 8.

FIG. 10 is a schematic sectional view illustrating an example of a cross-section taken along line B-B of the PVD apparatus illustrated in FIG. 8.

FIG. 11 is a schematic view for explaining an example of a positional relationship between a plurality of targets and a plurality of stages.

FIG. 12 is a schematic view for explaining another example of the positional relationship between the plurality of targets and the plurality of stages.

FIG. 13 is a block diagram of processing circuitry in accordance with an exemplary embodiment.

### DETAILED DESCRIPTION

Hereinafter, embodiments of the disclosed PVD apparatus will be described in detail with reference to the drawings. The PVD apparatus disclosed herein is not limited to the following embodiments.

In a conventional PVD apparatus, one substrate is accommodated in a chamber, and layer formation is performed on the accommodated one substrate. Therefore, it is difficult to improve the throughput of the layer formation processing with respect to a plurality of substrates.

Accordingly, the present disclosure provides a technology capable of improving the throughput of the layer formation processing with respect to the plurality of substrates.

[Manufacturing Method for a Semiconductor Device]

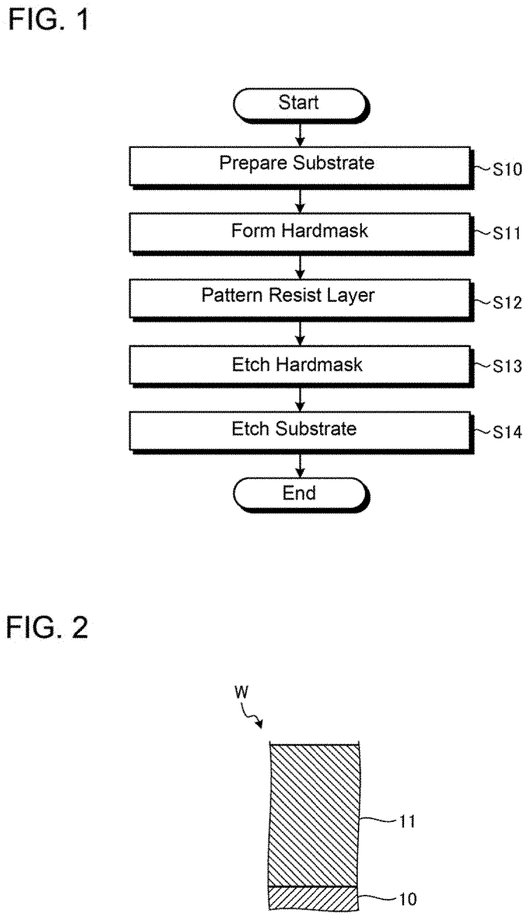

FIG. 1 is a flowchart illustrating an example of a semiconductor device manufacturing method according to an embodiment of the present disclosure. In the present embodiment, a semiconductor device is manufactured by processing a substrate W. Hereinafter, a processing procedure of the substrate W will be described with reference to FIGS. 2 to 6.

First, the substrate W to be a workpiece is prepared (S10). The substrate W prepared in step S10 includes, for example, as illustrated in FIG. 2, a base member 10 and a silicon-containing layer 11 stacked on the base member 10. The base member 10 is, for example, silicon. The silicon-containing layer 11 may be a single layer formed of any material including silicon such as a single crystal silicon layer, a polycrystalline silicon layer, a silicon oxide layer, or a silicon nitride layer. Further, the silicon-containing layer 11 may be a multilayer layer in which two or more layers selected from the single crystal silicon layer, the polycrystalline silicon layer, the silicon oxide layer, and the silicon nitride layer are stacked. The substrate W may have a structure in which another layer or a structure is provided between the base member 10 and the silicon-containing layer 11.

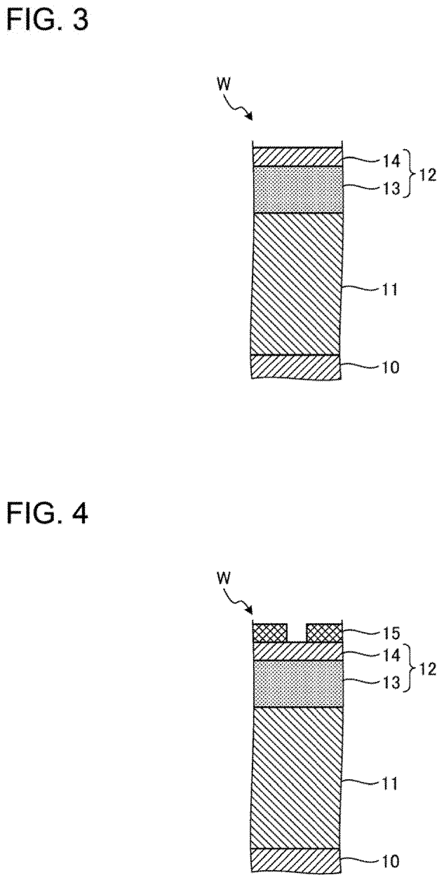

Next, a hardmask is formed on the substrate W (S11). Thus, for example, as illustrated in FIG. 3, the hardmask 12 is formed on the silicon-containing layer 11. The hardmask 12 includes a first hardmask 13 and a second hardmask 14. The first hardmask 13 is a mask for forming a hole or a trench (hereinafter referred to as a hole or the like) having a predetermined shape in the silicon-containing layer 11. The first hardmask 13 includes, for example, tungsten and silicon. Further, the first hardmask 13 is, for example, an amorphous layer.

Here, in a case where the hole or the like having a predetermined shape is formed in the silicon-containing layer 11 by plasma etching, a fluorine-containing gas is often used. In a case where the first hardmask 13 is formed by a chemical vapor deposition (CVD) method, the composition of the tungsten silicide in the first hardmask 13 is WSi₂. The tungsten silicide layer having such a composition includes a metal crystal. The layer that includes the metal crystal has low resistance to plasma etching at a crystal grain boundary, and is quickly etched at a portion where the crystal grain boundary is present.

In contrast, the first hardmask 13 of the present embodiment is an amorphous layer having substantially no crystal grain boundary. As such, the first hardmask 13 of the present embodiment has high resistance to plasma etching. In this way, in the plasma etching of the silicon-containing layer 11, it is possible to improve a local critical dimension uniformity (LCDU) of the hole or the like and a roundness of the hole.

The second hardmask 14 is a mask for forming the hole or the like having a predetermined shape in the first hardmask 13. In the present embodiment, the second hardmask 14 has, for example, a structure such that a carbon-containing layer is stacked on a silicon oxide layer formed by use of tetraethoxysilane (TEOS), and that a SiON layer is stacked on the carbon-containing layer.

Next, a resist layer 15 is stacked on the hardmask 12, and for example, as illustrated in FIG. 4, the resist layer 15 is patterned into a predetermined shape (S12).

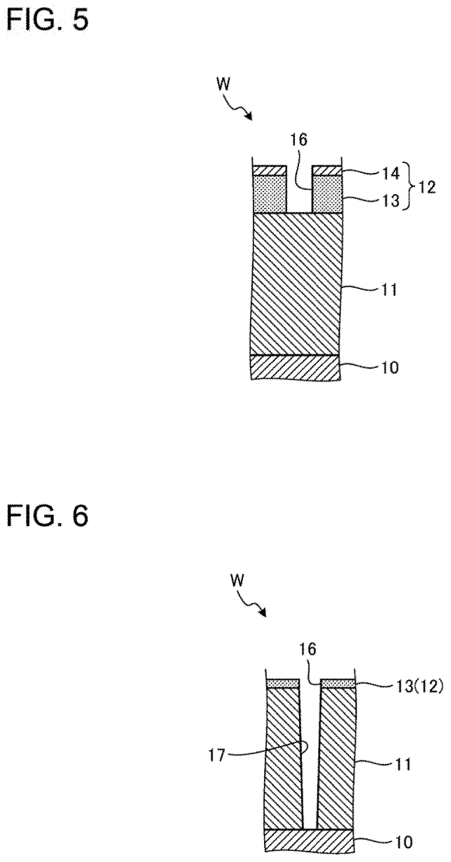

Next, the hardmask 12 is etched using the resist layer 15 as a mask patterned into a predetermined shape (S13). In this way, for example, as illustrated in FIG. 5, a hole 16 or the like corresponding to an opening of the resist layer 15 is formed in the first hardmask 13.

Next, the silicon-containing layer 11 underlying the first hardmask 13 is etched using the first hardmask 13 as a mask in which the hole 16 or the like is formed (S14). In this way, for example, as illustrated in FIG. 6, a hole 17 or the like corresponding to the hole 16 or the like of the first hardmask 13 is formed in the silicon-containing layer 11. Then, the manufacturing method for the semiconductor device illustrated in the flowchart of FIG. 1 is completed.

[Configuration of PVD System 100]

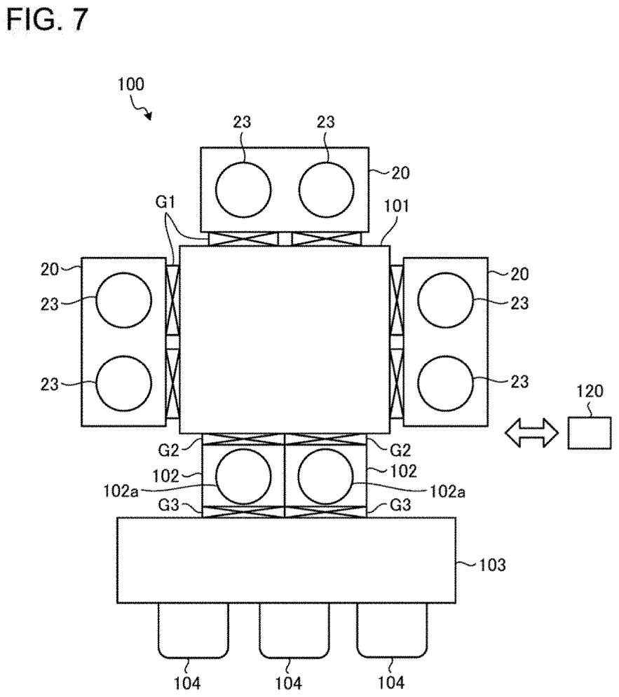

The first hardmask 13 is formed by, for example, a PVD system 100 illustrated in FIG. 7. FIG. 7 is a system configuration view illustrating an example of the PVD system 100 according to an embodiment of the present disclosure. In FIG. 7, for the sake of convenience of description, members in some of the apparatuses are drawn to be visible.

The PVD system 100 includes a vacuum transfer device 101, a plurality of load-lock devices 102, an atmospheric transfer device 103, a plurality of load ports 104, and a plurality of PVD apparatuses 20. The PVD system 100 is a multi-chamber type vacuum processing system. An inside of the vacuum transfer device 101 is evacuated by a vacuum pump to maintain a predetermined vacuum level. A transfer device such as a robot arm is provided inside the vacuum transfer device 101. The plurality of PVD apparatuses 20 are connected to sidewalls of the vacuum transfer device 101 via gate valves G1. In the example of FIG. 7, although three PVD apparatuses 20 are connected to the vacuum transfer device 101, the number of PVD apparatuses 20 connected to the vacuum transfer device 101 may be smaller than three or more than three.

Each PVD apparatus 20 performs the layer formation of the first hardmask 13 on the substrate W, which is a workpiece, by sputtering. A plurality of stages 23 on which one substrate W is placed are provided in each PVD apparatus 20. In the example of FIG. 7, although two stages 23 are provided inside of each PVD apparatus 20, the number of stages 23 provided inside of the PVD apparatus 20 may be more than two.

A plurality of load-lock devices 102 are connected to another sidewall of the vacuum transfer device 101 via gate valves G2. In the example of FIG. 7, although two load-lock devices 102 are connected to the vacuum transfer device 101, the number of load-lock devices 102 connected to the vacuum transfer device 101 may be smaller than two or more than two.

A stage 102a on which the substrate W is placed is provided inside of each load-lock device 102. The vacuum transfer device 101 is connected to one sidewall of each load-lock device 102 via the gate valve G2, and the atmospheric transfer device 103 is connected to the other one sidewall via the gate valve G3. A plurality of load ports 104 are provided on a sidewall of the atmospheric transfer device 103 opposite to a sidewall of the atmospheric transfer device 103 where the gate valve G3 is provided. A container such as a front opening unified pod (FOUP) capable of accommodating the plurality of substrates W is connected to each load port 104. The transfer device such as the robot arm is provided inside the atmospheric transfer device 103. The atmospheric transfer device 103 may be provided with an aligner device or the like that changes an orientation of the substrate W.

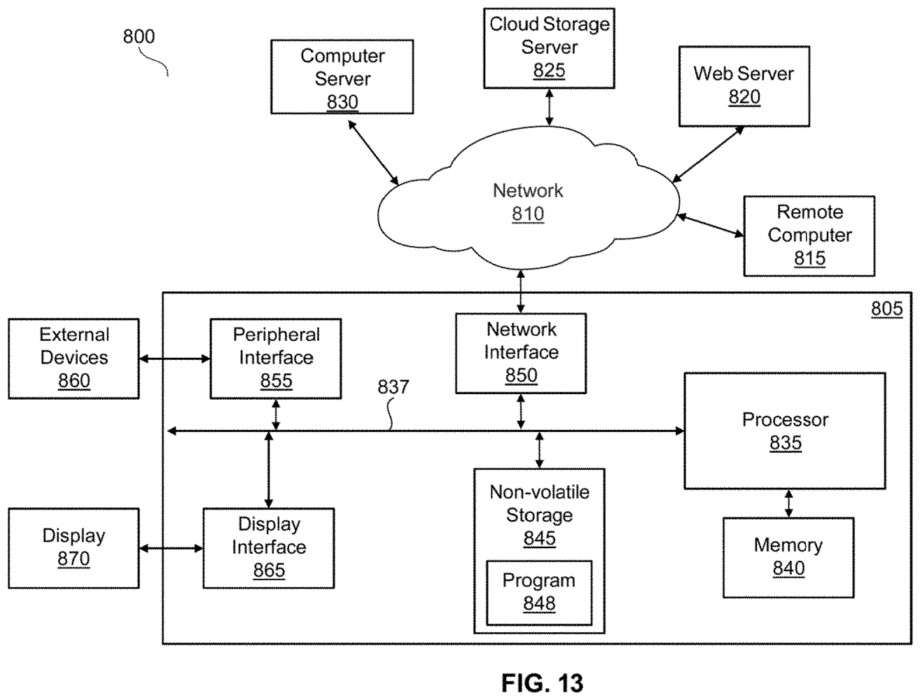

The controller 120 includes a memory, a processor, and an input/output interface. The memory stores data of e.g. a recipe, a program, and/or the like. The memory is, for example, a random access memory (RAM), a read only memory (ROM), a hard disk drive (HDD), a solid state drive (SSD), or the like. The processor executes a program read from the memory to control each portion of the PVD system 100 via the input/output interface based on the data of e.g. the recipe stored in the memory. The processor is, for example, a central processing unit (CPU) or a digital signal processor (DSP). The controller 120 may be implemented as the processing circuitry 805 discussed later in reference to FIG. 13.

For example, the controller 120 controls the transfer device inside the atmospheric transfer device 103 to take out the substrate W from the container connected to the load port 104 and transfer the substrate W into the load-lock device 102. The controller 120 controls the transfer device inside the vacuum transfer device 101 to take out the substrate W from the load-lock device 102 and place the substrate W on the stage 23 inside the PVD apparatus 20. Then, the controller 120 controls the PVD apparatus 20 so as to form the first hardmask 13 on the substrate W placed on the stage 23. Accordingly, the first hardmask 13 is formed on the substrate W.

[Structure of PVD Apparatus 20]

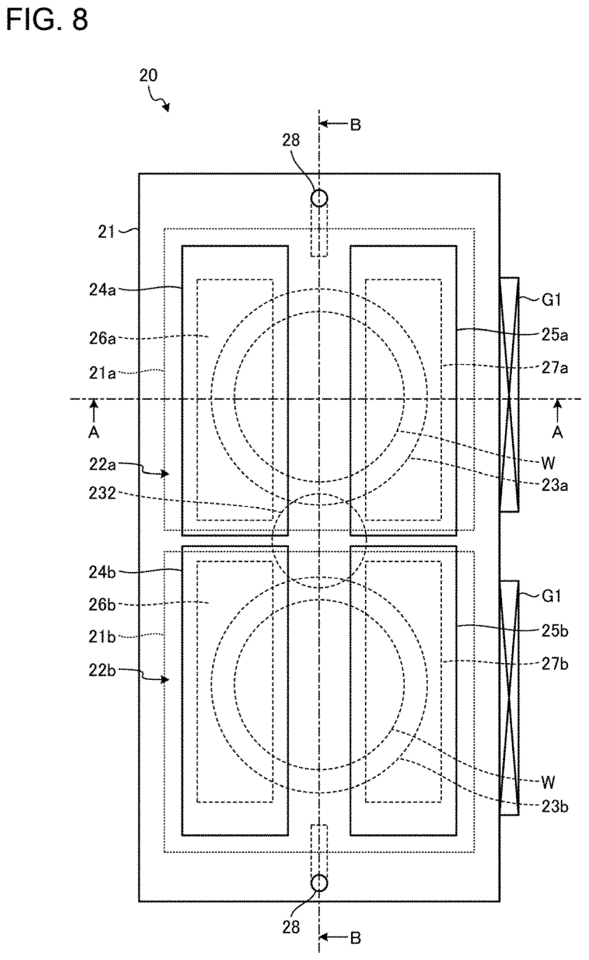

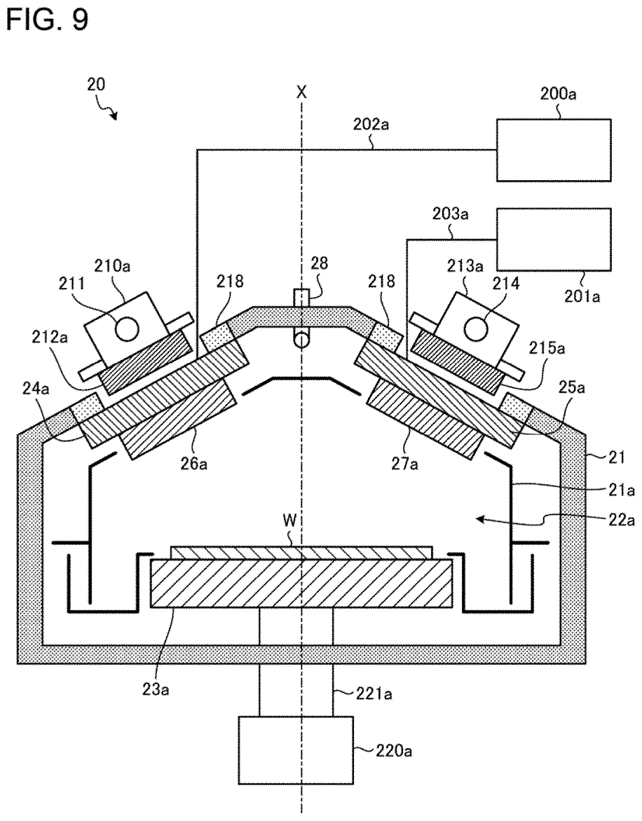

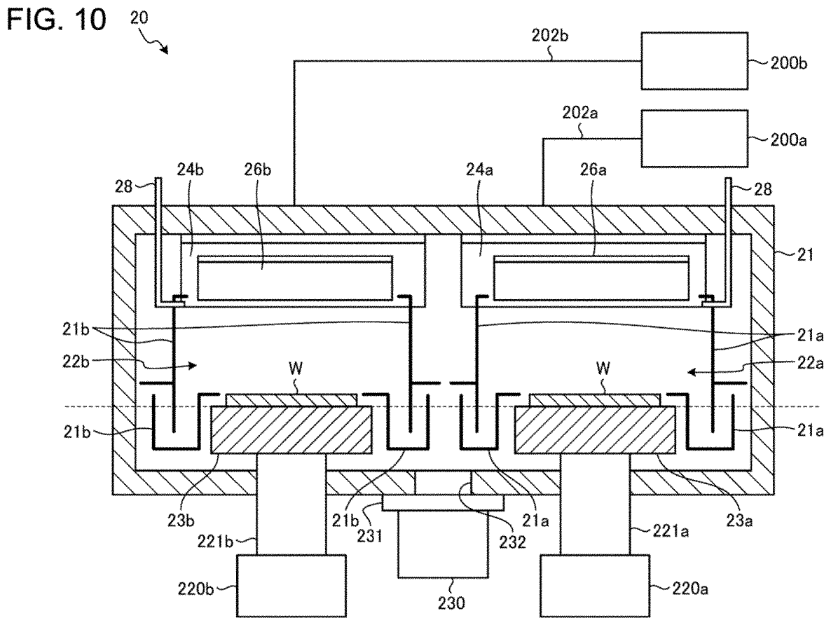

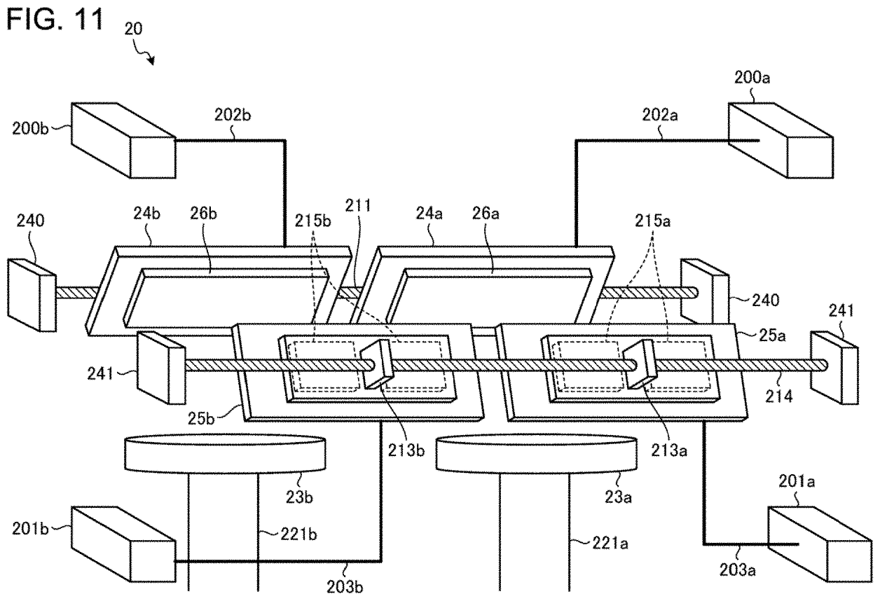

Next, a detailed structure of the PVD apparatus 20 will be described with reference to FIGS. 8 to 11. FIG. 8 is a schematic plan view illustrating an example of the PVD apparatus 20 according to an embodiment of the present disclosure. In FIG. 8, for the sake of convenience of description, some members of the PVD apparatus 20 are illustrated by broken lines. FIG. 9 is a schematic sectional view illustrating an example of a cross-section taken along line A-A of the PVD apparatus 20 illustrated in FIG. 8. FIG. 10 is a schematic sectional view illustrating an example of a cross-section taken along line B-B of the PVD apparatus 20 illustrated in FIG. 8. FIG. 11 is a schematic view for explaining an example of a positional relationship between a plurality of targets and a plurality of stages.

The PVD apparatus 20 has a chamber 21 formed of, for example, a conductive member such as aluminum. The chamber 21 is grounded. A plurality of openings through which the substrate W passes are formed in the sidewall of the chamber 21, and each of the openings is opened and closed by the gate valve G1.

A space inside the chamber 21 is divided into two processing spaces 22a and 22b by shields 21a and 21b. That is, a space inside the chamber 21 surrounded by the shield 21a is the processing space 22a, and a space inside the chamber 21 surrounded by the shield 21b is the processing space 22b. The processing space 22a is an example of a first processing space, and the processing space 22b is an example of a second processing space. In the present embodiment, although the space inside the PVD apparatus 20 is divided into two processing spaces 22a and 22b, the space inside the PVD apparatus 20 may be divided into two or more processing spaces by shields.

For example, as illustrated in FIG. 9, a stage 23a on which the substrate W is placed is provided inside the processing space 22a. Further, for example, as illustrated in FIG. 10, a stage 23b on which the substrate W is placed is provided in the processing space 22b. The stage 23a is an example of a first stage, and the stage 23b is an example of a second stage. The stage 23a and the stage 23b may have an electrostatic chuck that holds the substrate W. Further, the stage 23a and the stage 23b may have a temperature adjusting mechanism such as a heater.

For example, as illustrated in FIG. 10, a part of the shield 21a and a part of the shield 21b are disposed between the stage 23a and the stage 23b. That is, for example, as illustrated in FIG. 10, a part of the shield 21a is disposed closer to the support 221a than the position of the upper surface of the stage 23a (position indicated by a broken line in FIG. 10). Similarly, a part of the shield 21b is disposed closer to the support 221b than the position of the upper surface of the stage 23b (position indicated by the broken line in FIG. 10). Further, a part of the shield 21a and a part of the shield 21b are disposed between the processing space 22a on the stage 23a and the processing space 22b on the stage 23b.

For example, as illustrated in FIGS. 9 and 10, the stage 23a is supported by the substantially cylindrical support 221a extending from a portion immediately below the stage 23a to the outside of the chamber 21 through a bottom portion of the chamber 21. A sealing member such as a magnetic fluid seal is disposed between the support 221a and the bottom portion of the chamber 21. The driver 220a can adjust a height of the stage 23a by moving the support 221a up and down. Further, the driver 220a can rotate the support 221a around the central axis X of the stage 23a. When the support 221a rotates, the stage 23a rotates around the central axis X of the stage 23a.

For example, as illustrated in FIG. 10, the stage 23b is supported by the substantially cylindrical support 221b extending from a portion immediately below the stage 23b to the outside of the chamber 21 through the bottom portion of the chamber 21. A sealing member such as a magnetic fluid seal is disposed between the support 221b and the bottom portion of the chamber 21. The driver 220b can adjust a height of the stage 23b by moving the support 221b up and down. Further, the driver 220b can rotate the support 221b around the central axis of the stage 23b. When the support 221b rotates, the stage 23b rotates around the central axis of the stage 23b.

For example, as illustrated in FIG. 9, above the stage 23a, a target holder 24a and a target holder 25a formed of a conductive member are provided. The target holder 24a and the target holder 25a are fixed to a ceiling portion of the chamber 21 by a fixing member 218 formed of an insulator. The target holder 24a holds a target 26a. The target holder 25a holds a target 27a. For example, as illustrated in FIG. 9, the target holder 24a and the target holder 25a hold the target 26a and the target 27a to face each other across a plane passing through the central axis X of the stage 23a. The target 26a and the target 27a are an example of a first target. For example, as illustrated in FIG. 9, the target holder 24a holds the target 26a so as to be inclined such that a surface of the target 26a approaches the central axis X as being away from the stage 23a. For example, as illustrated in FIG. 9, the target holder 25a holds the target 27a so as to be inclined such that a surface of the target 27a approaches the central axis X as being away from the stage 23a.

In the present embodiment, one of the target 26a and the target 27a is a target including silicon, and the other is a target including tungsten. One of the target 26a and the target 27a may be a target including silicon and tungsten, and the other may be a target including tungsten. Further, at least one of the target 26a and the target 27a may include carbon.

A target holder 24b and a target holder 25b formed of a conductive member are provided above the stage 23b. The target holder 24b and the target holder 25b are fixed to the ceiling portion of the chamber 21 by a fixing member formed of an insulator. The target holder 24b holds the target 26b. The target holder 25b holds the target 27b. The target holder 24b and the target holder 25b hold the target 26b and the target 27b to face each other across a plane passing through the central axis of the stage 23b. The target 26b and the target 27b are an example of a second target. The target holder 24b holds the target 26b so as to be inclined such that a surface of the target 26b approaches the central axis of the stage 23b as being away from the stage 23b. The target holder 25b holds the target 27b so as to be inclined such that a surface of the target 27b approaches the central axis of the stage 23b as being away from the stage 23b.

In the present embodiment, one of the target 26b and the target 27b is a target including silicon, and the other is a target including tungsten. One of the target 26b and the target 27b may be a target including silicon and tungsten, and the other may be a target including tungsten. Further, at least one of the target 26b and the target 27b may include carbon.

For example, as illustrated in FIGS. 9 and 11, a power supply 200a is connected to the target holder 24a via a wiring 202a. The power supply 200a supplies DC or AC power to the target 26a via the wiring 202a and the target holder 24a. A power supply 201a is connected to the target holder 25a via a wiring 203a. The power supply 201a supplies the DC or AC power to the target 27a via the wiring 203a and the target holder 25a. The power supply 200a and the wiring 203a are an example of a power supply mechanism.

Further, for example, as illustrated in FIG. 11, a power supply 200b is connected to the target holder 24b via a wiring 202b. The power supply 200b supplies the DC or AC power to the target 26b via the wiring 202b and the target holder 24b. A power supply 201b is connected to the target holder 25b via a wiring 203b. The power supply 201b supplies the DC or AC power to the target 27b via the wiring 203b and the target holder 25b. The power supply 200b and the wiring 203b are an example of the power supply mechanism.

For example, as illustrated in FIG. 9, a magnet 212a is provided on a rear surface side of the surface of the target holder 24a where the target 26a is provided. The magnet 212a is held by a magnet holder 210a. A screw shaft 211 penetrates the magnet holder 210a. The magnet holder 210a reciprocates along the screw shaft 211. For example, as illustrated in FIG. 11, the screw shaft 211 is disposed along the target 26a. The screw shaft 211 is an example of a guide. A motor 240 rotates the screw shaft 211. The motor 240 is an example of a driver. When the screw shaft 211 rotates, the magnet holder 210a moves along the screw shaft 211. When the magnet holder 210a moves along the screw shaft 211, the magnet 212a held by the magnet holder 210a moves along the target 26a. In this way, it is possible to suppress the magnetic field generated from the magnet 212a to be locally concentrated on the target 26a, and to suppress the plasma to be locally concentrated on the target 26a. The magnet holder 210a, the screw shaft 211, and the motor 240 are an example of a driving mechanism.

For example, as illustrated in FIG. 9, a magnet 215a is provided on a rear surface side of the surface of the target holder 25a where the target 27a is provided. The magnet 215a is held by a magnet holder 213a. A screw shaft 214 penetrates the magnet holder 213a. The magnet holder 213a reciprocates along the screw shaft 214. For example, as illustrated in FIGS. 9 and 11, the screw shaft 214 is disposed along the target 27a. The screw shaft 214 is an example of a guide. A motor 241 rotates the screw shaft 214. The motor 241 is an example of a driver. When the screw shaft 214 rotates, the magnet holder 213a moves along the screw shaft 214. When the magnet holder 213a moves along the screw shaft 214, the magnet 215a held by the magnet holder 213a moves along the target 27a. In this way, it is possible to suppress the magnetic field generated from the magnet 215a to be locally concentrated on the target 27a, and to suppress the plasma to be locally concentrated on the target 27a. The magnet holder 213a, the screw shaft 214, and the motor 241 are an example of the driving mechanism.

Although it is not illustrated, a magnet 212b is provided on the rear surface side of the surface of the target holder 24b where the target 26b is provided. The magnet 212b is held by a magnet holder 210b. The screw shaft 211 penetrates the magnet holder 210b. The magnet holder 210b reciprocates along the screw shaft 211. For example, as illustrated in FIG. 11, the screw shaft 211 is disposed along the target 26b. When the motor 240 rotates the screw shaft 211, the magnet holder 210b moves along the screw shaft 211. When the magnet holder 210b moves along the screw shaft 211, the magnet 212b held by the magnet holder 210b moves along the target 26b. In this way, it is possible to suppress the magnetic field generated from the magnet 212b to be locally concentrated on the target 26b, and to suppress the plasma to be locally concentrated on the target 26b. The magnet holder 210b, the screw shaft 211, and the motor 240 are an example of the driving mechanism.

For example, as illustrated in FIG. 11, a magnet 215b is provided on a rear surface side of the surface of the target holder 25b where the target 27b is provided. The magnet 215b is held by a magnet holder 213b. The screw shaft 214 penetrates the magnet holder 213b. The magnet holder 213b reciprocates along the screw shaft 214. For example, as illustrated in FIG. 11, the screw shaft 214 is disposed along the target 27b. When the motor 241 rotates the screw shaft 214, the magnet holder 213b moves along the screw shaft 214. When the magnet holder 213b moves along the screw shaft 214, the magnet 215b held by the magnet holder 213b moves along the target 27b. In this way, it is possible to suppress the magnetic field generated from the magnet 215b to be locally concentrated on the target 27b, and to suppress the plasma to be locally concentrated on the target 27b. The magnet holder 213b, the screw shaft 214, and the motor 241 are an example of the driving mechanism.

Further, for example, as illustrated in FIG. 11, the screw shaft 211 penetrates the magnet holder 210a and the magnet holder 210b. When the motor 240 rotates, the magnet holder 210a holding the magnet 212a and the magnet holder 210b holding the magnet 212b move along the screw shaft 211. Accordingly, a plurality of magnets can be reciprocated by one screw shaft 214 and one motor 241. Similarly, the screw shaft 214 penetrates the magnet holder 213a and the magnet holder 213b. When the motor 241 rotates, the magnet holder 213a holding the magnet 215a and the magnet holder 213b holding the magnet 215b move along the screw shaft 214. Accordingly, a plurality of magnets can be reciprocated by one screw shaft 214 and one motor 241.

A pipe 28 is connected to the chamber 21. A gas supply is connected to the pipe 28. The gas supply supplies an inert gas such as a rare gas or a nitrogen gas to the processing space 22a and the processing space 22b inside the chamber 21 via the pipe 28. The pipe 28 and the gas supply are an example of a gas supply mechanism.

Further, for example, as illustrated in FIGS. 8 and 10, an exhaust port 232 is formed at the bottom portion of the chamber 21. An exhaust device 230 is connected to the exhaust port 232 via an automatic pressure control (APC) valve 231. The exhaust device 230 includes a decompression pump such as a dry pump and a turbo molecular pump. The exhaust device 230 and the APC valve 231 are an example of an exhaust mechanism.

In the PVD apparatus 20 of the present embodiment, the gas is supplied from the pipe 28 into the chamber 21 provided with the processing space 22a and the processing space 22b where the substrates W are respectively disposed, and the gas is exhausted from the exhaust port 232. That is, the pipe 28 for supplying the gas and the exhaust port 232 for exhausting the gas are each commonly provided inside the chamber 21 having the processing space 22a and the processing space 22b. As such, it is possible to reduce a pressure difference between the processing space 22a and the processing space 22b. In this way, it is possible to suppress fluctuation to be low in the characteristics of the substrate W formed in each of the processing space 22a and the processing space 22b.

In the PVD apparatus 20 having such a configuration, for example, the first hardmask 13 is formed on the substrate W through the following procedure. First, two gate valves G1 are opened, the two substrates W are carried into the chamber 21, and the substrates W are respectively placed on the stage 23a and the stage 23b. Then, the heights of the stage 23a and the stage 23b are adjusted by the driver 220a and the driver 220b, respectively. Then, the driver 220a and the driver 220b start the rotation of the stage 23a and the stage 23b, respectively.

Next, the supply of the inert gas from the gas supply into the chamber 21 is started via the pipe 28, and the exhaust device 230 starts to exhaust the gas inside the chamber 21. Then, the pressure inside the chamber 21 is adjusted by the APC valve 231.

Next, supplies of the power are started from the power supply 200a to the target 26a, from the power supply 201a to the target 27a, from the power supply 200b to the target 26b, and from the power supply 201b to the target 27b, respectively. In this way, plasma is generated inside each of the processing space 22a and the processing space 22b. Then, ions in the plasma collide with the target 26a, the target 26b, the target 27a, and the target 27b, so that respective constituent substances are released from the target 26a, the target 26b, the target 27a, and the target 27b. Then, the released constituent substance is deposited on the substrate W, so that the first hardmask 13 is formed on the substrate W.

Then, the motor 240 rotates the screw shaft 211 in a forward rotation direction and a reverse rotation direction, so that the magnet 212a and the magnet 212b start reciprocating movement along the screw shaft 211. Further, when the motor 241 rotates the screw shaft 214 in the forward rotation direction and the reverse rotation direction, the magnet 215a and the magnet 215b start reciprocating movement along the screw shaft 214. In this way, local concentration of plasma on the target 26a, the target 26b, the target 27a, and the target 27b is alleviated.

In the processing space 22a, in a case where only the constituent substance in either one of the target 26a and the target 27a is deposited on the substrate W, the power may be supplied to only either one of the target 26a and the target 27a. Similarly, in a case where only the constituent substance in either one of the target 26b and the target 27b is deposited on the substrate W, the power may be supplied to only either one of the target 26b and the target 27b. In this case, the motor reciprocates only the magnet disposed in the vicinity of the target to which the power is supplied.

In this way, in the PVD apparatus 20 of the present embodiment, since the layer formation can be performed on two substrates W, it is possible to improve the throughput of the layer formation processing on a plurality of substrates W, compared to a single-wafer PVD apparatus in which layer formation is performed on one substrate W. Further, in the PVD apparatus 20 of the present embodiment, it is possible to perform layer formation on two substrates W in parallel. Therefore, as compared with a single-wafer PVD apparatus in which the layer formation is performed on one substrate W, it is possible to suppress fluctuation to be low in the characteristics of the substrate W in a case where the layer formation processing is performed on the plurality of substrates W. In the PVD apparatus 20 of the present embodiment, although the layer formation is performed on two substrates W, the technology disclosed herein is not limited thereto, and the layer formation may be performed on more than two substrates W. Therefore, throughput of the layer formation processing with respect to the plurality of substrates W can be further improved, and it is possible to further suppress fluctuation to be low in the characteristics of the substrate W.

[Test Results]

Here, test results obtained by performing the processing illustrated in FIG. 1 on the substrate W (see FIG. 4) including the first hardmask 13 formed by the PVD apparatus 20 of the present embodiment will be described. In step S13, the second hardmask 14 was etched using the resist layer 15 as a mask patterned in step S12, and a hole having a critical dimension (CD) of 22 nm was formed in the second hardmask 14. Then, the first hardmask 13 was etched using the second hardmask 14 as the mask in which the hole was formed. The first hardmask 13 might be a single layer formed of any material including silicon such as a silicon oxide layer or a silicon nitride layer. The etching of the first hardmask 13 was performed under the following conditions. Pressures: 10 mTorr

Radio frequency (RF) power: upper electrode/lower electrode=200 W/300 W

Etch gas: Cl₂/O₂/N₂/Ar

In the LCDU of the first hardmask 13 after the etching, the same value as amorphous silicon (tungsten concentration 0 at. %) was obtained.

In step S14, the silicon-containing layer 11 is etched by plasma etching using the first hardmask 13 as the mask. The etching of the silicon-containing layer 11 was performed under the following conditions. Pressures: 10 mTorr

RF power: upper electrode/lower electrode=1500 W/10000 W

Etch gas: NF₃/C₄F₆/C₄F₈/O₂

Since the first hardmask 13 was also etched during the etching of the silicon-containing layer 11, the selectivity was calculated by taking the etched layer thickness of the silicon-containing layer 11 and the etched layer thickness of the first hardmask 13 as a ratio. In a case where the tungsten concentration was 60 at. %, a high selectivity that was more than twice that of amorphous silicon (tungsten concentration: 0 at. %) was obtained. When the selectivity is high, for example, in a case where the amorphous silicon has a layer thickness of 600 nm, by using tungsten silicon for the first hardmask 13, the thickness can be thinned to 400 nm. Generally, when the hardmask layer thickness is thinned, the ions during the etching can be attracted vertically, so that twisting of the hole or the like having a high aspect ratio can be suppressed.

An embodiment of the present disclosure has been described above. The PVD apparatus 20 in the present embodiment includes the chamber 21, the plurality of stages, the plurality of targets, the holder, and the power supply mechanism. The plurality of stages are provided inside the chamber 21, and one substrate W is placed on each stage. The plurality of targets are exposed to the space inside the chamber 21, and at least one target is provided for one stage. The holder holds the target. The power supply mechanism supplies power to the target via the holder. The gas supply mechanism supplies a gas into the chamber 21. The gas supply mechanism exhausts the gas inside the chamber 21. Therefore, it is possible to improve the throughput of the layer formation processing with respect to the plurality of substrates W.

The PVD apparatus 20 in the embodiment described above includes the plurality of magnets and the driving mechanism. The plurality of magnets are provided on the rear surface side of the surface of the target holder on which the target is provided, and one magnet is provided for one target. The driving mechanism moves the plurality of magnets along the rear surface of the surface of the target holder on which the target is provided. In this way, it is possible to suppress the magnetic field generated from the magnet to be locally concentrated on the target, and to suppress the plasma to be locally concentrated on the target.

Further, in the PVD apparatus 20 in the embodiment described above, the plurality of stages are disposed side by side along the moving direction of the magnet. Further, the target holder holds the plurality of targets such that the plurality of targets are aligned along the moving direction of the magnet. The driving mechanism includes the guide, the plurality of magnet holders, and the driver. The guide extends along the moving direction of the magnet. The plurality of magnet holders hold the magnets and move along the guide. The driver reciprocates the plurality of magnet holders along the guide. Accordingly, the plurality of magnets can be reciprocated by one guide and one driver.

Further, the PVD apparatus 20 in the embodiment described above includes the shield 21a and the shield 21b provided inside the chamber 21. The shield 21a and the shield 21b separate the processing space 22a between the first targets provided corresponding to the stage 23a and the stage 23a, and the processing space 22b between the second targets provided corresponding to the stage 23b and the stage 23b. Therefore, it is possible to perform the layer formation on each substrate W under individually predetermined conditions inside one chamber 21.

In the PVD apparatus 20 in the embodiment described above, two targets 26a and 27a are provided for one stage 23a. One of the target 26a and the target 27a includes a constituent substance which is not included in the other of the target 26a or the target 27a. Therefore, a layer in which different substances are mixed can be formed on the substrate W.

(Other)

The technology disclosed in the present application is not limited to the above-described embodiment, and various modifications are possible within the scope of the gist thereof.

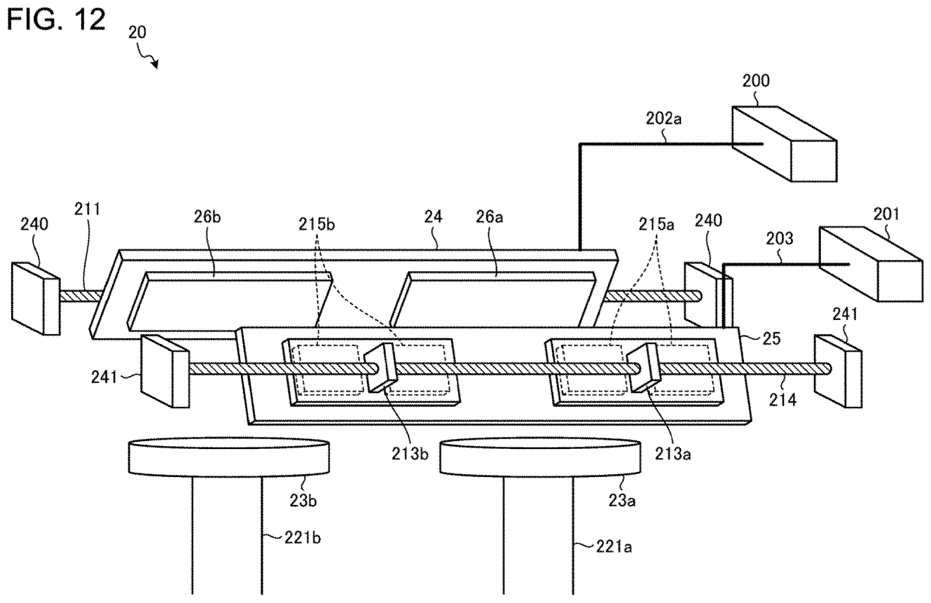

For example, in the PVD apparatus 20 of the embodiment described above, the power is supplied from the power supply 200a to the target 26a via the target holder 24a, and the power is supplied from the power supply 200b to the target 26b via the target holder 24b. In the PVD apparatus 20 of the embodiment described above, the power is supplied from the power supply 201a to the target 27a via the target holder 25a, and the power is supplied from the power supply 201b to the target 27b via the target holder 25b. However, the technology disclosed herein is not limited thereto. As another form, for example, as illustrated in FIG. 12, the target 26a and the target 26b may be held by one target holder 24, and the target 27a and the target 27b may be held by one target holder 25. In the example of FIG. 12, the target holder 24 and the target holder 25 extend along an array direction of the plurality of stages 23a and 23b. The power supply 200 may supply the power to the target 26a and the target 26b via wiring the 202 and the target holder 24. Further, the power supply 201 may supply the power to the target 27a and the target 27b via the wiring 203 and the target holder 25. As such, the number of the power supplies 200, the power supplies 201, the wirings 202, and the wirings 203 can be reduced. Therefore, it is possible to suppress fluctuation in the characteristics of the layer formation caused by an error in a magnitude and/or the like of the power output from the power supply 200 and the power supply 201, and an error in a resistance value and/or the like of the wiring 202 and the wiring 203.

It shall be understood that the embodiments disclosed herein are illustrative and are not restrictive in all aspects. Indeed, the above-described embodiments can be implemented in various forms. The embodiments described above may be omitted, replaced, or modified in various forms without departing from the scope and spirit of the appended claims.

FIG. 13 is a block diagram of processing circuitry for performing computer-based operations described herein. FIG. 13 illustrates processing circuitry 805 that may be used to control any computer-based control processes, descriptions or blocks in flowcharts can be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art. The various elements, features, and processes described herein may be used independently of one another or may be combined in various ways. All possible combinations and sub-combinations are intended to fall within the scope of this disclosure.

In FIG. 13, the processing circuitry 805 includes a processor (CPU) 835 which performs one or more of the control processes described above/below. The process data and instructions may be stored in memory 840. These processes and instructions (e.g., program 848) may also be stored on a storage medium disk 845 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the processing circuitry 805 communicates, such as a server or computer.

Further, the claimed advancements may be provided as a utility application, background daemon, or component of an operating system, or combination thereof, executing in conjunction with CPU 835 and an operating system such as Microsoft Windows, UNIX, Solaris, LINUX, Apple MAC-OS and other systems known to those skilled in the art.

The hardware elements in order to achieve the processing circuitry 805 may be realized by various circuitry elements. Further, each of the functions of the above described embodiments may be implemented by circuitry, which includes one or more processing circuits. A processing circuit includes a particularly programmed processor, for example, processor (CPU) 835, as shown in FIG. 13. A processing circuit also includes devices such as an application specific integrated circuit (ASIC) and conventional circuit components arranged to perform the recited functions.

In FIG. 13, the processing circuitry 805 includes a CPU 835 which performs the processes described above. The processing circuitry 805 may be a general-purpose computer or a particular, special-purpose machine.

Alternatively, or additionally, the CPU 835 may be implemented on an FPGA, ASIC, PLD or using discrete logic circuits, as one of ordinary skill in the art would recognize. Further, CPU 835 may be implemented as multiple processors cooperatively working in parallel to perform the instructions of the inventive processes described above.

The processing circuitry 805 in FIG. 13 also includes a network controller such as an Intel Ethernet PRO network interface card from Intel Corporation of America, for interfacing with network 810 via the network interface 850. As can be appreciated, the network 810 can be a public network, such as the Internet, or a private network such as an LAN or WAN network, or any combination thereof and can also include PSTN or ISDN sub-networks. The network 810 can also be wired, such as an Ethernet network, or can be wireless such as a cellular network including EDGE, 3G and 4G wireless cellular systems. The wireless network can also be Wi-Fi, Bluetooth, or any other wireless form of communication that is known.

The processing circuitry 805 further includes a display controller/display interface 865, such as a graphics card or graphics adaptor for interfacing with display 870, such as a monitor. A peripheral interface 855 interfaces with external devices 860 such as a keyboard, mouse, touch screen panel, etc. Peripheral interface 855 also connects to a variety of peripherals including printers and scanners. A processing circuitry system 800 can include the processing circuitry 805, along with a computer server 830, a cloud storage server 825, a web server 820, and a remote computer 815 which are connected to the processing circuitry 805 via the network 810. A description of the general features and functionality of the display 870, keyboard and/or mouse, as well as the display interface 865, the peripheral interface 855, the network interface 850, the computer server 830, the cloud storage server 825, the web server 820, and the remote computer 815 is omitted herein for brevity as these features are known.

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset.

The functions and features described herein may also be executed by various distributed components of a system. For example, one or more processors may execute these system functions, wherein the processors are distributed across multiple components communicating in a network. The distributed components may include one or more client and server machines, which may share processing, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope that may be claimed.

Having now described embodiments of the disclosed subject matter, it should be apparent to those skilled in the art that the foregoing is merely illustrative and not limiting, having been presented by way of example only. Thus, although particular configurations have been discussed herein, other configurations can also be employed. Numerous modifications and other embodiments (e.g., combinations, rearrangements, etc.) are enabled by the present disclosure and are within the scope of one of ordinary skill in the art and are contemplated as falling within the scope of the disclosed subject matter and any equivalents thereto. Features of the disclosed embodiments can be combined, rearranged, omitted, etc., within the scope of the invention to produce additional embodiments. Furthermore, certain features may sometimes be used to advantage without a corresponding use of other features. Accordingly, Applicant(s) intend(s) to embrace all such alternatives, modifications, equivalents, and variations that are within the spirit and scope of the disclosed subject matter.

The exemplary embodiments according to the present disclosure have been described by way of example, and various changes may be made without departing from the scope and spirit of the present disclosure. The exemplary embodiments disclosed above are thus not restrictive, and the true scope and spirit of the present disclosure are defined by the appended claims.

1. A PVD apparatus comprising:
a chamber;
a plurality of stages which are provided inside the chamber and each of which is configured to place at least one substrate on an upper surface thereof;
a first target holder to hold at least one target provided for one of the stages, the target being exposed to a space inside the chamber;
a power supply that supplies power to the target via the first target holder; and
a shield which is provided inside the chamber and a part of which is disposed between a first stage and a second stage in the plurality of stages, and between a first processing space on the first stage and a second processing space on the second stage.

2. A PVD apparatus comprising:
a chamber;
a plurality of stages which are provided inside the chamber and each of which is configured to place at least one substrate on an upper surface thereof;
a first target holder to hold at least one target provided for one of the stages, the target being exposed to a space inside the chamber;
a power supply that supplies power to the target via the first target holder;
a plurality of magnets which are provided on a rear surface side of a surface of the first target holder on which the target is provided, and at least one of which is provided for one target; and
a driver that moves the plurality of magnets along the rear surface,
wherein the plurality of stages are disposed side by side along a moving direction of the magnet,
the first target holder is configured to hold a plurality of the targets such that the plurality of targets are disposed side by side along the moving direction, and
the driver includes a guide that extends along the moving direction,
a plurality of magnet holders that hold the magnets and move along the guide, and
a second driver that reciprocates the plurality of magnet holders along the guide.

3. The PVD apparatus according to claim 1,
wherein the first target holder extends along an array direction of the plurality of stages, and holds a plurality of targets, and
the power supply is configured to supply the power to each of the plurality of targets via the first target holder by supplying the power to the first target holder.

4. The PVD apparatus according to claim 1, further comprising:
a second target holder to hold the target at an angle different from that of the first target holder for the one of the stages.

5. The PVD apparatus according to claim 1,
wherein the first target holder extends along an array direction of the plurality of stages, and holds a plurality of targets.

6. The PVD apparatus according to claim 1, further comprising:
a second target holder to hold the target.

7. The PVD apparatus according to claim 2,
wherein the first target holder extends along an array direction of the plurality of stages, and holds a plurality of the targets, and
the power supply is configured to supply the power to each of the plurality of targets via the first target holder by supplying the power to the first target holder.

8. The PVD apparatus according to claim 2, further comprising:
a second target holder to hold the target at an angle different from that of the first target holder for the one of the stages.

9. The PVD apparatus according to claim 2,
wherein the first target holder extends along an array direction of the plurality of stages, and holds a plurality of targets.

10. The PVD apparatus according to claim 2, further comprising:
a second target holder to hold the target.

11. The PVD apparatus according to claim 3, further comprising:
a second target holder to hold the target at an angle different from that of the first target holder for the one of the stages.

12. The PVD apparatus according to claim 7, further comprising:
a second target holder to hold the target at an angle different from that of the first target holder for the one of the stages.

13. A PVD apparatus comprising:
a chamber;
a plurality of stages which are provided inside the chamber and each of which is configured to place at least one substrate on an upper surface thereof;
a first target holder to hold at least one target provided for one of the stages, the target being exposed to a space inside the chamber;
a power supply that supplies power to the target via the first target holder;
a plurality of magnets which are provided on a rear surface side of a surface of the first target holder on which the target is provided, and at least one of which is provided for one target; and
a shield which is provided inside the chamber and a part of which is disposed between a first stage and a second stage in the plurality of stages, and between a first processing space on the first stage and a second processing space on the second stage.

14. The PVD apparatus according to claim 13,
wherein the first target holder extends along an array direction of the plurality of stages, and holds a plurality of the targets, and
the power supply is configured to supply the power to each of the plurality of targets via the first target holder by supplying the power to the first target holder.

15. The PVD apparatus according to claim 13, further comprising:
a second target holder to hold the target at an angle different from that of the first target holder for the one of the stages.

16. The PVD apparatus according to claim 14, further comprising:
a second target holder to hold the target at an angle different from that of the first target holder for the one of the stages.

17. The PVD apparatus according to claim 13,
wherein the first target holder extends along an array direction of the plurality of stages, and holds a plurality of targets.

18. The PVD apparatus according to claim 13, further comprising:
a second target holder to hold the target.
